(19) United States
(12) Patent Application Publication
(10) Pub. No.: US 2012/0238086 A1
(43) Pub. Date: Sep. 20, 2012

(54) REDUCING EQUIVALENT THICKNESS OF HIGH-K DIELECTRICS IN FIELD EFFECT TRANSISTORS BY PERFORMING A LOW TEMPERATURE ANNEAL

(75) Inventors: Klaus Hempel, Dresden (DE); Robert Binder, Dresden (DE); Joachim Metzger, Butzbach (DE)

(73) Assignee: GLOBALFOUNDRIES INC., Grand Cayman (KY)

(21) Appl. No.: 13/422,221

(22) Filed: Mar. 16, 2012

(30) Foreign Application Priority Data
Mar. 17, 2011 (DE) 10 2011 005 718.8

(51) Int. Cl. H01L 21/28

(52) U.S. Cl. 438/591; 257/E21.191

(57) ABSTRACT

When forming sophisticated high-k metal gate electrode structures, for instance on the basis of a replacement gate approach, superior interface characteristics may be obtained on the basis of using a thermally grown base material, wherein the electrically effective thickness may be reduced on the basis of a low temperature anneal process. Consequently, the superior interface characteristics of a thermally grown base material may be provided without requiring high temperature anneal processes, as are typically applied in conventional strategies using a very thin oxide layer formed on the basis of a wet oxidation chemistry.

### BACKGROUND OF THE INVENTION

1. Field of the Invention

Generally, the present disclosure relates to sophisticated integrated circuits including high-performance transistors formed on the basis of a high-k dielectric material.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the scaling of the channel length, and associated therewith the reduction of channel resistivity, is a dominant design criterion for accomplishing an increase in the operating speed of the integrated circuits.

Presently, most complex integrated circuits are based on silicon due to its substantially unlimited availability, the well-understood characteristics of silicon and related materials and processes and the experience gathered during the last 50 years. Therefore, silicon will likely remain the material of choice for future circuit generations designed for mass products. One reason for the dominant importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a gate insulation layer that separates the gate electrode, frequently comprised of polysilicon, from the silicon channel region. In steadily improving device performance of field effect transistors, the length of the channel region has been continuously decreased to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. The short channel behavior may lead to an increased leakage current and to a dependence of the threshold voltage on the channel length. Aggressively scaled transistor devices with a relatively low supply voltage and thus reduced threshold voltage may suffer from an exponential increase of the leakage current, when the thickness of the silicon dioxide layer is correspondingly decreased to provide the required capacitance between the gate and the channel region. For example, a channel length of approximately 0.08 μm may require a gate dielectric made of silicon dioxide as thin as approximately 1.2 nm. Although, generally, high speed transistor elements having an extremely short channel may preferably be used for high speed applications, whereas transistor elements with a longer channel may be used for less critical applications, such as storage transistor elements, the relatively high leakage current caused by direct tunneling of charge carriers through an ultra-thin silicon dioxide gate insulation layer may reach values for an oxide thickness in the range of 1-2 nm that may represent limitations for performance driven circuits. That is, product reliability and lifetime are strongly correlated with short channel effects, i.e., impact ionization and hot carrier injection (HCI) in combination with gate dielectric leakage.

A further reduction in thickness of well-established conventional dielectric materials, such as nitrogen-enriched silicon dioxide, is thus no longer compatible with requirements of high performance semiconductor devices. For this reason, other strategies have been proposed and are increasingly implemented in sophisticated manufacturing techniques. For example, it has been suggested to use so-called high-k dielectric materials, which are to be understood as dielectric materials having a significantly higher dielectric constant compared to nitrogen-enriched silicon dioxide, silicon nitride and the like. In this application, a high-k dielectric material is to be understood as a dielectric material having a dielectric constant of 10.0 and higher. For example, a plurality of metal oxides, metal silicates and the like may be used as efficient dielectric materials, for instance in the form of hafnium oxide, zirconium oxide and the like. It turns out, however, that simply replacing a conventional gate dielectric material with a high-k dielectric material so as to obtain an oxide equivalent thickness of approximately 1 nm and less with a physical thickness that is appropriate for reducing overall gate leakage currents may result in reduced overall transistor performance. For example, significant mobility degradation has been observed in transistors formed on the basis of a high-k dielectric material that is directly formed on the silicon base material of the channel region. Similarly, reduced reliability, i.e., reduced lifetime, and significant variability of transistor characteristics have been observed. For these reasons, a conventional dielectric material, such as a silicon dioxide material, is provided in combination with a high-k dielectric material so as to implement superior interface characteristics, wherein, in view of obtaining a high capacitive coupling, it is desirable to reduce the thickness of the silicon oxide base material as much as possible. For example, a layer thickness of 0.8 nm and even less, which may correspond to only a few atomic layers, may be implemented on the basis of sophisticated wet chemical oxidation techniques, which provide a highly controllable and self-limiting process flow. On the other hand, well-established thermal oxidation techniques, i.e., oxidation processes performed in an oxidizing gaseous atmosphere, as have typically been applied for forming conventional gate dielectric materials in a highly controllable manner, may result in an increased layer thickness, thereby reducing the capacitive coupling obtained in combination with a specific high-k dielectric material. Typically, a thermal oxidation may result in a layer thickness of a silicon oxide material that is 2-4 Å greater compared to an oxide material formed on the basis of sophisticated wet chemical oxidation processes. On the other hand, it turns out that generally the interface characteristics of a wet chemical oxidized base material in combination with a high-k dielectric material are inferior with respect to thermally grown oxide materials, which may result in increased threshold voltages, in particular for P-channel transistors due to the aforementioned further parasitic defect degradation mechanisms. For example, particularly the incorporation of interface states may result in unstable and unduly high threshold voltages of P-channel transistors when applying sophisticated wet chemical oxidation techniques in combination with high-k dielectric materials, such as hafnium oxide. Therefore, in some conventional approaches, additional anneal processes may be implemented which, however, may result in significant constraints with respect to overall process flexibility, as will be described in more detail with reference to FIGS. 1a-1g.

FIG. 1a schematically illustrates a cross-sectional view of a semiconductor device 100 in a very advanced manufacturing stage. As shown, the device 100 comprises a substrate 101, such as a semiconductor material or any other appropriate carrier material, above which is provided a semiconductor layer 102, which may form a silicon-on-insulator (SOI) configuration with the substrate 101 when a buried insulating material (not shown) is formed directly below the semiconductor layer 102, while, in other cases, a bulk configuration may be formed by the components 101, 102 when the semiconductor layer 102 is a portion of a crystalline semiconductor material of the substrate 101. The semiconductor layer 102 is typically laterally divided into a plurality of active regions, which are to be understood as semiconductor regions in and above which one or more transistors are to be formed. For example, in FIG. 1a, a single active region 102A is illustrated and corresponds to a transistor 150, such as a P-channel transistor. Consequently, appropriate drain and source regions 151 are implemented in the active region 102A in accordance with the overall transistor requirements. Furthermore, a gate electrode structure 160 is formed on the active region 102A and represents, according to well-established process techniques, a placeholder gate electrode structure which may be “converted” into the actual gate electrode structure during the further processing. Any such manufacturing strategies may frequently be referred to as a replacement gate approach. In the stage shown in FIG. 1a, the gate electrode structure 160 may comprise a dielectric material 161 formed on the active region 102A in combination with a placeholder material 162, such as a polysilicon material and the like. Furthermore, an appropriate spacer structure 163 may be provided in accordance with the overall process and device requirements. Furthermore, at least a portion of a contact level 120 is provided in this manufacturing stage and comprises a first dielectric material 121, such as a silicon nitride material, which is also frequently referred to as an etch stop material. Furthermore, an interlayer dielectric material 122, for instance in the form of a silicon dioxide material, is provided so as to laterally enclose and passivate the transistor 150.

The semiconductor device 100 as shown in FIG. 1a may be formed on the basis of any well-established process technique in which the active region 102A may be formed by providing appropriate isolation regions 102C, which thus laterally delineate the corresponding active regions. To this end, sophisticated process techniques may be applied, for instance, when forming shallow trench isolations. Prior to or after forming the isolation region 102C, the appropriate basic dopant concentration is implemented in the active region 102A and thereafter the gate electrode structure 160 is formed, for instance, by providing the dielectric material 161, for instance in the form of a silicon dioxide material, which may be formed by applying well-established thermal oxidation techniques, as discussed above, while in other cases the material 161 may be deposited. Thereafter, any appropriate placeholder material 162, such as polysilicon and the like, is deposited and further materials such as hard mask materials (not shown) and the like are provided and finally patterned so as to obtain the gate electrode structure 160 with the desired lateral dimensions. For example, a length of the gate electrode structure 160, i.e., in FIG. 1a, the horizontal extension of the material 162, may be 50 nm and significantly less in complex semiconductor devices. Thereafter, the spacer structure 163 in combination with the drain and source regions 151 are provided, which may be accomplished by well-established process techniques. Next, the dielectric materials of the contact level 120 are deposited, for instance by plasma enhanced chemical vapor deposition (CVD) followed by a planarization sequence in which finally a surface of the material 162 is exposed so as to enable the removal of the material 162 on the basis of any appropriate highly selective etch process. To this end, wet chemical etch chemistries, plasma assisted etch chemistries and the like may be applied.

It should be appreciated that, in view of forming a sophisticated high-k dielectric material in the gate electrode structure 160, certain constraints may have to be taken into consideration, for instance avoiding any temperature-sensitive materials and the like, since further anneal processes may be required upon incorporating the high-k dielectric material in order to provide superior interface characteristics, which may be associated with the implementation of a wet chemical oxidation process in combination with a high-k dielectric material. For example, in many conventional replacement gate approaches, corresponding contact regions in the drain and source regions 151 may be formed in a later manufacturing stage, for instance in the form of a metal silicide, since typically these materials are not compatible with the performing of high temperature anneal processes.

FIG. 1b schematically illustrates the device 100 according to some illustrative process strategies in which an etch process 103 is applied so as to remove the layer 161 and thus expose a surface 102S of the active region 102A. The process 103 may be performed on the basis of well-established wet chemical etch techniques having a high degree of selectivity without unduly affecting the quality of the surface 102S. If required, any additional processes may be applied, such as anneal processes and the like, in order to improve the quality of the surface 102S prior to forming a very thin silicon oxide layer on the basis of wet chemical oxidation processes.

FIG. 1c schematically illustrates the device 100 during a wet chemical oxidation process 104, which may be performed on the basis of well-established chemicals, which results in a highly controllable and even in a self-limiting oxidation behavior, thereby forming a dielectric material 164A on the exposed surface 102S with a thickness of 8 Å or less, depending on the specifics of the oxidation process 104.

FIG. 1d schematically illustrates the device 100 in a further advanced manufacturing stage in which a highly controllable deposition process 105 is applied in order to form a layer of a high-k dielectric material 164B on any exposed surface areas of the device 100 and thus on the previously formed oxide layer 164A. To this end, well-established CVD-like process techniques, such as atomic layer deposition (ALD), which is a self-limiting deposition process usually based on two different precursor materials and the like, are applied. For example, hafnium oxide may be deposited with a thickness of 1 nm and higher so as to provide the desired physical thickness, while nevertheless a desired equivalent oxide thickness of approximately 1 nm and less may be achieved. It should be appreciated that an equivalent oxide thickness is to be understood as a thickness that would provide the same static capacitive coupling as an oxide layer.

FIG. 1e schematically illustrates an enlarged view of a portion of the semiconductor device 100. As discussed above, generally, the interface characteristics, i.e., the characteristics at the surface 102S are inferior due to the formation of the oxide layer 164A on the basis of wet chemical oxidation techniques in combination with the deposition of the material 164B. For this reason, in some strategies, a high temperature anneal process 106 is typically applied, for instance, after the deposition of the high-k dielectric material 164B in order to enhance the overall interface characteristics so as to reduce the finally obtained threshold voltage, while also increasing reliability and stability of the gate dielectric material 164 formed from the oxide layer 164A and the high-k dielectric material layer 164B. To this end, typically, temperatures of up to 1000° C. are applied, which may significantly enhance the overall interface characteristics, which may, however, also result in a certain shift of the characteristics of the gate dielectric material 164.

FIG. 1f schematically illustrates the device 100 after the high temperature anneal process 106 of FIG. 1e. It has been observed that, although interface stability and reliability may be improved, an increase of the electrically effective thickness, indicated by 164I of the gate dielectric material 164 is observed. The thickness 164I is to be understood as the oxide equivalent thickness in a state in which a conductive channel 153 forms at or in the vicinity of the surface 102S, as indicated by charge carriers 153E. That is, as schematically indicated by an increased thickness of the layer 164A, generally the interface thickness of the gate dielectric material 164 may increase by several Å, thereby increasing the thickness 164I compared to the situation prior to the high temperature anneal process 106 of FIG. 1e.

FIG. 1g schematically illustrates the semiconductor device 100 in a further advanced manufacturing stage. As shown, metal-containing electrode materials 165 are formed on the gate dielectric material 164 and are typically used for adjusting an appropriate work function and enabling an appropriate manufacturing process for defining work function values and thus threshold voltage values for transistors of different conductivity type and generally of different transistor characteristics. For example, frequently, a stack of layers including titanium nitride, tantalum nitride, tantalum and the like may be used. For example, a titanium nitride layer 165A having a thickness of 2 nm and less, followed by a tantalum nitride layer 165B having a thickness of 2 nm and less may be applied in combination with a titanium nitride cap layer 165C having a thickness of 5-10 nm. The layer stack 165 may be formed on the basis of well-established ALD techniques and the like. Thereafter, a highly conductive electrode metal 169, for instance in the form of aluminum, aluminum alloys and the like, is deposited, followed by a material removal process, such as a chemical mechanical polishing (CMP) process, in which the conductive layers 165, 169 may be removed from horizontal device areas, thereby providing the gate electrode structure 160 as an electrically isolated element having superior conductivity and enhanced capacitive coupling due to the provision of the high-k dielectric material 164. It turns out, however, that the process sequence described above may result in improved interface quality of the gate dielectric material compared to extremely thin wet chemically oxidized layers without a high temperature anneal, while nevertheless the finally obtained threshold voltage and transistor characteristics are less than desired, whereas significant constraints with respect to the overall process flexibility are associated with the high temperature anneal process.

In view of the situation described above, the present disclosure relates to manufacturing techniques in which sophisticated high-k dielectric materials may be provided, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques in which low threshold voltage and high reliability values may be achieved, while at the same time a desired low electrically effective oxide equivalent thickness may be achieved. To this end, a high-k gate dielectric material may be formed on the basis of a thermally grown base dielectric material, for instance formed on the basis of a thermal oxidation process, so as to initially provide superior interface characteristics, whereas the final equivalent thickness may be adjusted by performing an additional low temperature anneal process in the presence of at least the high-k dielectric material, thereby further reducing the equivalent thickness without negatively affecting the overall interface characteristics. In some illustrative embodiments disclosed herein, the low temperature anneal process may be performed in a reducing process atmosphere, while in other cases, in addition or alternatively to the reducing ambient, a plasma may be established with a high degree of uniformity and with reduced probability of creating plasma-induced damage, for instance by using slot plane antenna (SPA) anneal processes. In this manner, the high-k dielectric material may be formed on the basis of significantly lower process temperatures, thereby obtaining superior flexibility in designing the overall process flow.

One illustrative method disclosed herein comprises performing an oxidation process in a gaseous oxidizing atmosphere so as to form an oxide layer on an exposed silicon-containing surface of a semiconductor region of a semiconductor device. The method further comprises forming a layer of a high-k dielectric material on the oxide layer. Moreover, the method comprises performing a heat treatment at a temperature of 500° C. and less so as to form a gate dielectric material from the oxide layer and the layer of a high-k dielectric material. Additionally, the method comprises forming a gate electrode structure of a field effect transistor on the basis of the gate dielectric material.

A further illustrative method disclosed herein relates to forming a high-k dielectric material. The method comprises forming a first dielectric layer on an exposed silicon-containing semiconductor surface in a gaseous reactive process atmosphere. The method further comprises forming a high-k dielectric material on the first dielectric layer. Additionally, the method comprises performing an anneal process in a reducing atmosphere at a temperature of 500° C. or less.

A still further illustrative method disclosed herein comprises exposing a top surface of a placeholder material of a gate electrode structure of a semiconductor device. Furthermore, the method comprises removing the placeholder material so as to expose a silicon-containing surface of a semiconductor region. The method further comprises forming a gate dielectric material on the silicon-containing surface by thermally oxidizing the silicon-containing surface by forming a high-k dielectric layer on the oxidized silicon-containing surface and by performing an anneal process. The method additionally comprises forming a metal-containing electrode material above the gate dielectric material.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1g schematically illustrate cross-sectional views of a semiconductor device during various manufacturing stages when forming a sophisticated high-k metal gate electrode structure on the basis of a replacement gate approach using a high temperature anneal process for improving interface characteristics, according to conventional strategies;

FIGS. 2a-2c schematically illustrate cross-sectional views of a semiconductor device during a manufacturing sequence in which a high-k dielectric material may be formed on the basis of a dielectric base material formed by applying a gaseous process atmosphere, such as an oxidizing atmosphere, in combination with a low temperature anneal process in the presence of a high-k dielectric material, according to illustrative embodiments;

FIG. 2d schematically illustrates the semiconductor device according to illustrative embodiments in which a gate electrode structure may be provided on the basis of the high-k dielectric material having superior equivalent thickness and interface characteristics;

FIGS. 2e-2f schematically illustrate cross-sectional views of the semiconductor device according to illustrative embodiments in which a high-k dielectric gate material may be formed in a late manufacturing stage in the context of a replacement gate approach while providing superior process flexibility in forming temperature sensitive materials; and

FIG. 2g schematically illustrates a cross-sectional view of the semiconductor device according to still further illustrative embodiments in which temperature sensitive materials such as metal silicides, self-aligned contact elements and the like may be formed prior to incorporating a sophisticated high-k gate dielectric material on the basis of process strategies as described above.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides manufacturing techniques in which sophisticated high-k dielectric materials, as may be used for gate dielectrics, capacitor dielectrics and the like, may be provided on the basis of conventional dielectric base materials having superior interface characteristics in combination with any appropriate high-k dielectric layer, wherein a subsequent low temperature anneal process may be applied so as to reduce the electrically equivalent thickness of the resulting high-k dielectric material while still preserving high interface qualities, enhanced reliability of the resulting high-k dielectric material, which may thus translate into superior reliability of transistors, increased threshold voltage stability, while generally the electrically effective equivalent thickness may be less compared to highly sophisticated conventional gate dielectric materials. To this end, the base material may be formed on the basis of any thermally activated process, such as an oxidation process, possibly in combination with a nitridation process by using appropriate process temperatures, which may be significantly lower compared to high temperature anneal processes as are typically applied in conventional process strategies in which a chemically oxidized surface layer may be exposed to temperatures of up to 1000° C. For example, a plurality of highly controllable oxidation and/or nitridation process regimes are available on the basis of temperatures of 500° C. and significantly less so that an appropriate dielectric material layer with high interface quality may be formed at any desired manufacturing stage, for instance after forming any other sensitive materials such as metal silicides, contact materials and the like. It should be appreciated that, in the context of this application, a thermal oxidation or generally a thermally activated process performed in a “gaseous” atmosphere is to be understood as a thermal oxidation and/or nitridation process, wherein at least the components oxygen and/or nitrogen are supplied by gaseous components in the process atmosphere without providing any reactive process liquids, as is typically the case in chemical oxidation processes.

In some illustrative embodiments, the low temperature anneal process applied to the thermally grown base layer and the high-k dielectric layer may be performed at a temperature of 500° C. and less, and in particular embodiments at a temperature of 300° C. and less, wherein additionally a reducing process ambient may be established. For example, in some illustrative embodiments, oxygen may be added to the process atmosphere in a gaseous form in combination with nitrogen and/or hydrogen, thereby achieving a significant reduction of the electrically effective equivalent thickness of the resulting high-k dielectric material while preserving superior interface quality. In some illustrative embodiments, the low temperature anneal process may be applied in the form of a slot plane antenna plasma process environment, for which appropriate process tools are available, for instance from TEL. Generally, in an SPA anneal process, a plasma may be established by a specific configuration of the antenna using high frequency energy having a frequency of several GHz, so that generally a very low electron temperature may be obtained in the vicinity of the substrate surface to be treated. In this manner, any plasma-induced damage may be significantly reduced, while at the same time very uniform process conditions may be established across substrates, such as 300 mm substrates and the like. In some illustrative embodiments, a corresponding plasma-induced thermal oxidation process may be applied, wherein even temperatures of 200° C. and less may be used, thereby obtaining a significant reduction of the electrically effective equivalent thickness compared to the initial layer stack comprising the thermally grown base material and the high-k dielectric layer.

In some illustrative embodiments, a corresponding SPA process regime may also be applied in forming the dielectric base material on an exposed silicon-containing surface, thereby providing superior uniformity and highly controllable process conditions, while at the same time very low process temperatures may be used, thereby even further increasing the overall flexibility in implementing the process for forming a sophisticated high-k dielectric material into an overall process flow.

In some illustrative embodiments disclosed herein, forming a high-k gate dielectric material may be combined with the deposition of an appropriate electrode material, for instance in the form of titanium nitride and the like, wherein a non-controlled exposure to oxygen and nitrogen may be avoided or at least significantly reduced by performing the low temperature anneal process in the presence of at least one metal-containing electrode material, which may be deposited in situ with respect to the high-k dielectric material.

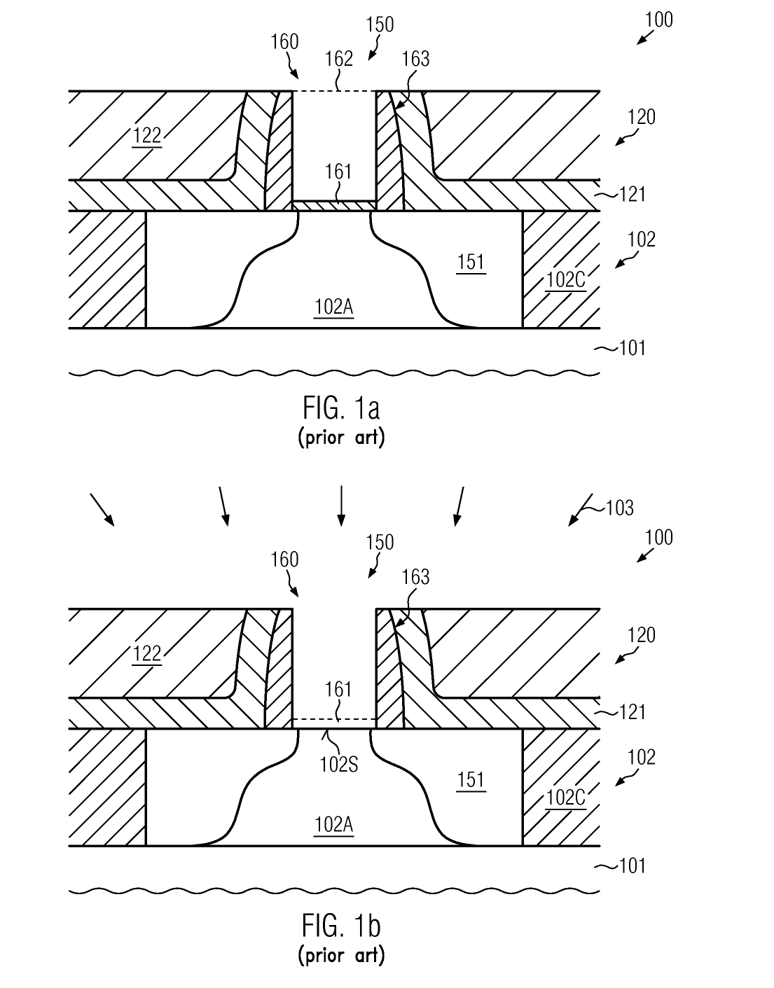

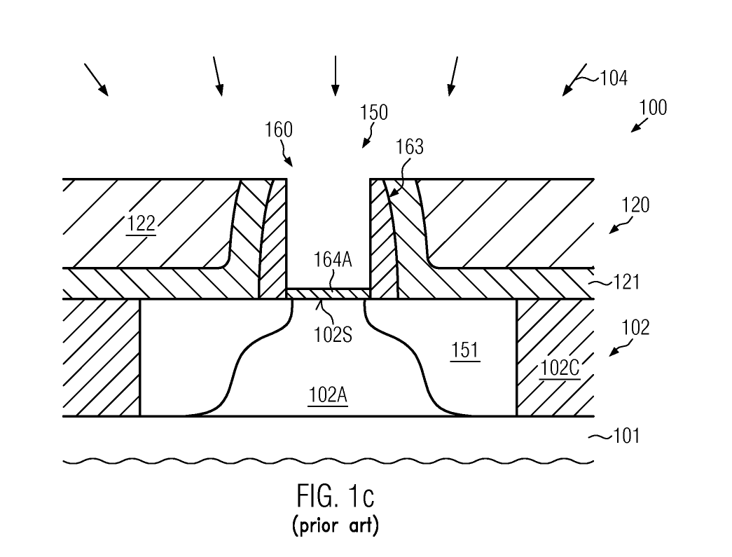

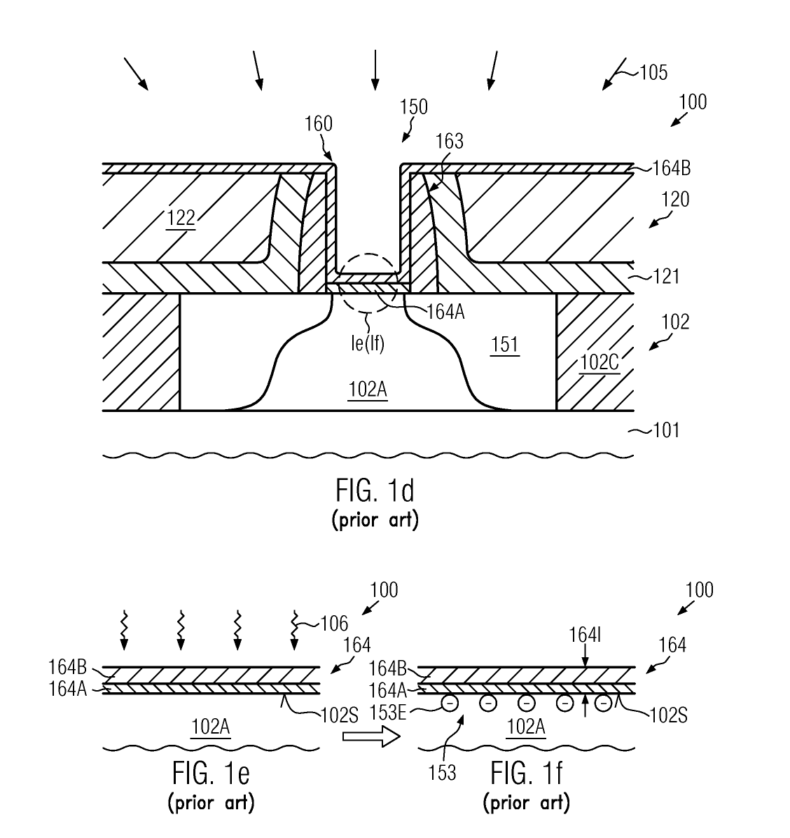

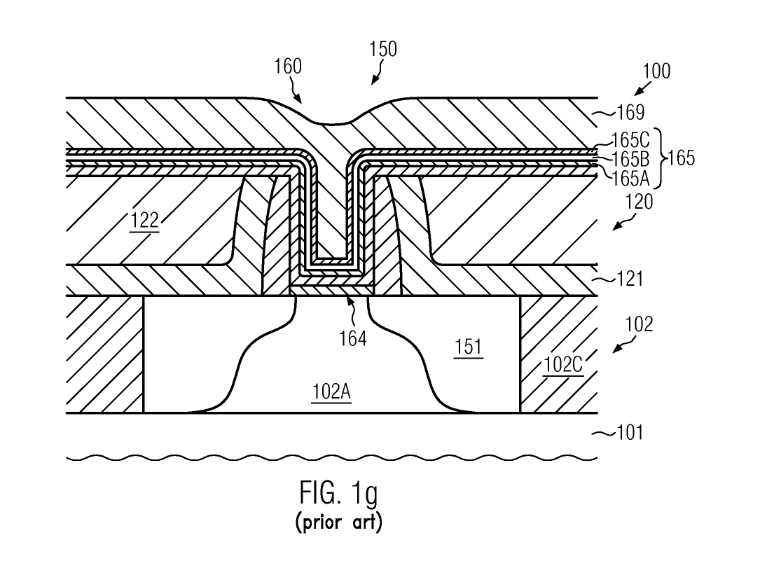

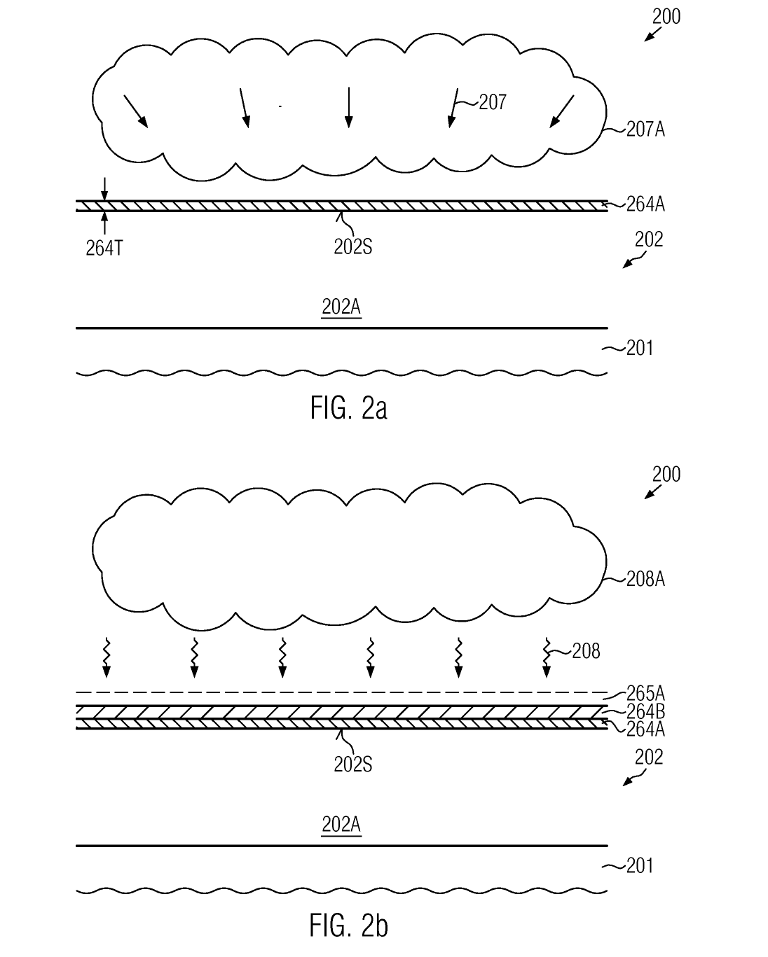

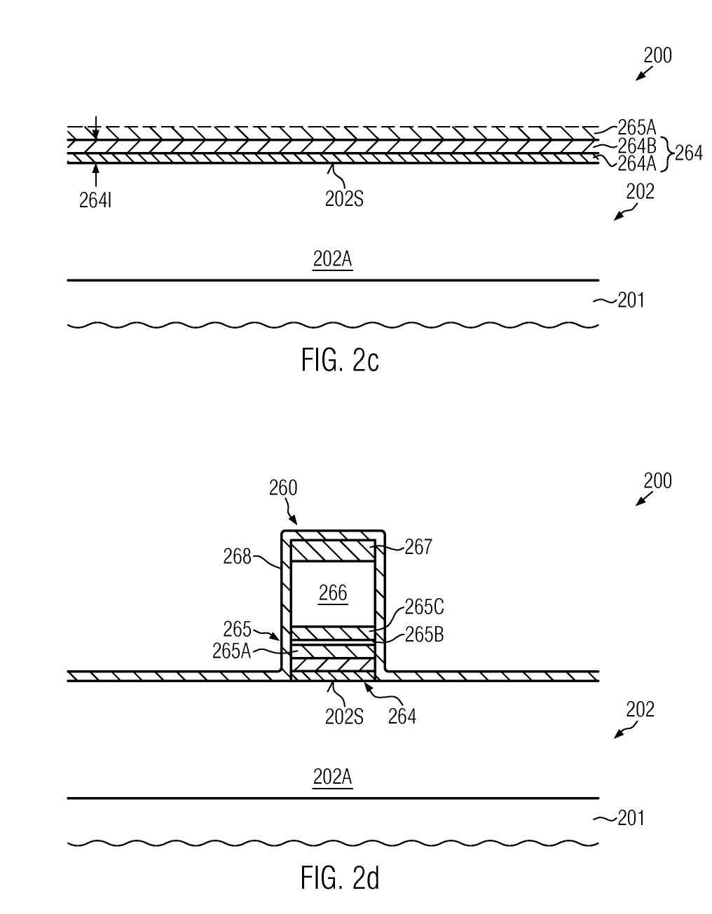

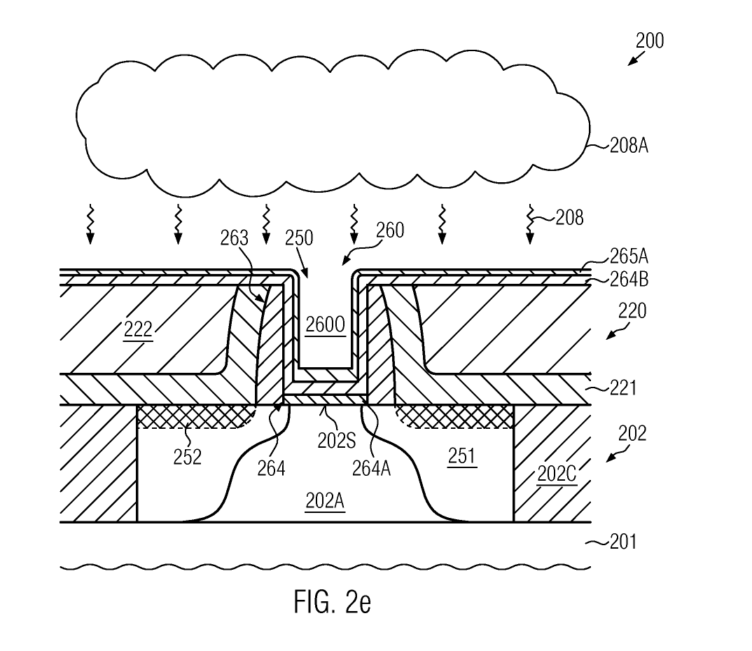

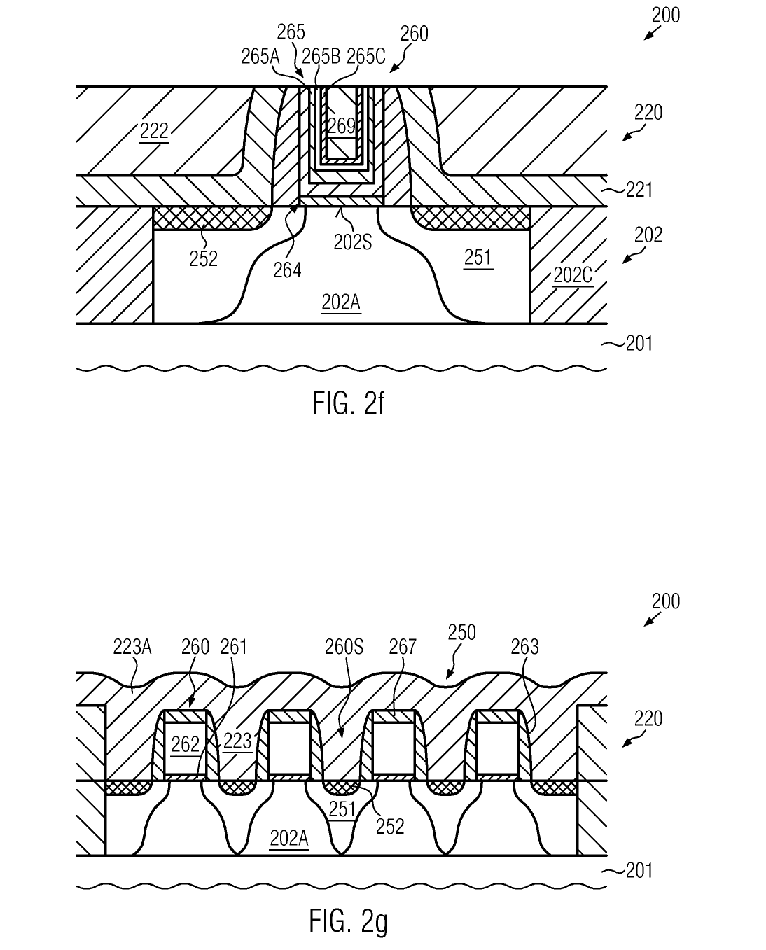

With reference to FIGS. 2a-2g, further illustrative embodiments will now be described in more detail, wherein reference may also be made to FIGS. 1a-1g, if appropriate.

FIG. 2a schematically illustrates a cross-sectional view of a semiconductor device 200 in a process stage in which a high-k dielectric material is to be formed on an exposed copper-containing surface. As shown, the device 200 may comprise a substrate 201 and a semiconductor layer 202, which may comprise a certain amount of silicon in order to provide a silicon-containing surface 202S. As discussed above with reference to the device 100, the semiconductor layer 202 and the substrate 201 may form an SOI configuration or a bulk configuration, as required. Furthermore, as discussed above, the semiconductor layer 202 may comprise a plurality of active regions, wherein, for convenience, a single active region 202A is illustrated in FIG. 2a. Furthermore, in the process stage shown, a dielectric base layer 264A, for instance an oxide layer, may be formed during a thermally driven process 207 in a gaseous process atmosphere 207A. As discussed above, the gaseous atmosphere 207A is to be understood as a process ambient in which, in particular, the oxygen may be provided in the form of gas components without requiring the application of any reactive process liquids. The process 207 may thus be considered as a thermal oxidation process when basically the layer 264A is formed as an oxide layer, for instance such as a silicon dioxide layer and the like. It should be appreciated, however, that the surface 202S may comprise other atomic species in a non-negligible fraction, such as germanium, carbon and the like. In other cases, the base layer 264A may also be formed on the basis of a nitrogen species, such as a silicon nitride layer, while in other cases an oxygen and nitrogen-containing base material may be formed. To this end, a plurality of thermal oxidation processes or oxidation processes in combination with nitridation processes are available in which appropriate process temperatures and gas atmospheres may be established. In some illustrative embodiments, the gaseous atmosphere 207A may be established on the basis of plasma, for instance by using a slot plane antenna process environment, as described above. Thus, in some illustrative embodiments, a temperature of 500° C. and less may be applied upon forming the layer 264A having a desired thickness 264T, for instance in the range of approximately 1 nm and less.

FIG. 2b schematically illustrates the device 200 in a further advanced manufacturing stage. As shown, a high-k dielectric layer 264B may be formed on the base dielectric layer 264A and may have any appropriate material composition. For example, for sophisticated transistors, frequently hafnium oxide may be used, while in other cases other appropriate materials such as zirconium oxide, aluminum oxide or metal/silicon compounds may be used. The deposition of the high-k dielectric layer 264B may be accomplished by using well-established deposition techniques, such as ALD and the like, as is also discussed above with reference to the device 100. Consequently, the layer 264B may be provided with a well controllable thickness and material composition in accordance with the overall process requirements. It should be appreciated that generally the interface characteristics at the surface 202S may be substantially determined by the material 264A, which has been formed on the basis of a thermal process, thereby providing superior interface characteristics compared to sophisticated wet chemical oxidation processes. In some illustrative embodiments, a further material layer 265A, for instance in the form of a metal-containing electrode material, may be provided, in some illustrative embodiments, in the same deposition ambient as the material 264B thereby avoiding undue exposure to ambient atmosphere of the material 264B. In this case, the layers 264B, 265A may be formed on the basis of an in situ process without breaking the vacuum conditions upon depositing the materials 264B, 265A. For example, a titanium nitride material may be formed on the basis of ALD techniques with a thickness as required by the overall process and device requirements. For example, the layer 265A may be provided with a thickness of 2 nm and less. In other cases, the layer 265A may be provided in a later manufacturing stage. Thereafter, at least the layers 264B, 264A may be exposed to a low temperature anneal process 208, in which temperatures of 500° C. and significantly less may be applied so as to further enhance the characteristics of a resulting high-k dielectric material formed from the layers 264A, 264B. For example, in particular the electrically effective equivalent thickness of these layers may be reduced during the low temperature anneal process 208. In some illustrative embodiments, temperatures of 300° C. and less may be applied during the process 208. Consequently, a high degree of flexibility with respect to positioning the process of forming a high-k dielectric material within a complex manufacturing sequence for forming semiconductor devices may be achieved. In some illustrative embodiments, the anneal process 208 may be performed on the basis of an appropriate gaseous atmosphere 208A, which may comprise, in some illustrative embodiments, oxygen and nitrogen, while in other cases oxygen and hydrogen may be applied. In still other illustrative embodiments, generally the atmosphere 208A may represent a reducing process atmosphere, which may be established on the basis of, for instance, the components described above and any combination thereof. In some illustrative embodiments, the atmosphere 208A may be established in an SPA process environment, thereby contributing to superior uniformity and controllability, while very low process temperatures, for instance of even 200° C. and less, may be applied.

FIG. 2c schematically illustrates the device 200 in a further advanced manufacturing stage. As illustrated, a dielectric material 264, such as a gate dielectric material, a capacitor dielectric, may be formed on the surface 202S from the layers 264A, 264B. Moreover, in this process stage, at least the layer 265A may be provided, for instance in the form of a titanium nitride material as discussed above. It should be appreciated that an electrically effective thickness 264I may be reduced compared to a corresponding thickness of the layers 264A, 264B prior to performing the low temperature anneal process 208 (FIG. 2b), thereby providing superior device characteristics, such as reduced threshold voltage transistors, while at the same time the desired high quality of the interface at the surface 202S may be preserved or even further improved. For example, the high-k dielectric material 264 may represent a compound formed from components of the layers 264A, 264B which are still illustrated as individual separate components, which, however, may have formed therebetween a corresponding transition area or may have been converted into a different material composition. For example, based on a silicon oxide layer and a hafnium oxide material, the dielectric material 264 may be understood as a dielectric material having generally the form of a hafnium silicon oxide compound with a varying stoichiometric composition depending on the previously applied process conditions. On the other hand, superior interface characteristics may be obtained or preserved, while the thickness 264I may be reduced. It should be understood that generally the thickness 264I may be measured on the basis of well-established electric test regimes.

FIG. 2d schematically illustrates the device 200 according to illustrative embodiments in which a gate electrode structure 260 may be formed on the basis of the high-k dielectric material 264. For example, in some illustrative embodiments, the gate electrode structure 260 may comprise a stack of metal-containing materials 265, for instance comprising the layer 265A in combination with further layers 265B, 265C. For example, the layers 265B, 265C may be comprised of tantalum nitride, titanium nitride and the like. It should further be appreciated that, if required, additional metal species, such as aluminum, lanthanum and the like, may be incorporated in one or more of the layers 265. Moreover, a further electrode material 266, such as amorphous silicon, polysilicon and the like, may be provided in combination with a dielectric cap layer 267, wherein also a protective liner 268, for instance in the form of a silicon nitride material, may be provided.

The gate electrode structure 260 as shown in FIG. 2d may be formed on the basis of process techniques including the deposition of the materials 265B, 265C in combination with the materials 266 and 267, followed by sophisticated lithography and patterning strategies so as to obtain desired lateral dimensions for the gate electrode structure 260. Thereafter, the liner 268 may be provided by applying multi-layer deposition techniques, low pressure CVD and the like. Thereafter, the processing may be continued by completing the basic transistor structure, i.e., forming drain and source regions in the active region 202A, possibly in combination with forming an appropriate spacer structure and the like. Consequently, in this case, the gate electrode structure 260 comprising the dielectric material 264 having the reduced electrically effective thickness and having superior interface characteristics may be formed in an early manufacturing stage. In other cases, the dielectric material 264 may be formed in a later manufacturing stage.

FIG. 2e schematically illustrates the semiconductor device 200 according to further illustrative embodiments in which a transistor 250 may be formed in and above the active region 202A and may be provided in a very advanced manufacturing stage. As shown, a gate electrode structure 260 may be provided and may represent a placeholder gate electrode structure, as is also discussed above with reference to the semiconductor device 100. That is, the gate electrode structure 260 may be laterally embedded in the dielectric material or materials of a contact level 220. For example, an etch stop layer 221 in combination with an interlayer dielectric material 222 may be provided. Furthermore, a spacer structure 263 may be formed in the gate electrode structure 260 as required for providing drain and source regions 251 so as to have a desired lateral and vertical dopant profile. Furthermore, as shown, a gate opening 260O may be provided which may be obtained by removing one or more placeholder materials of the gate electrode structure 260, such as a dielectric etch stop material in combination with a polysilicon material and the like, as is also described above with reference to the device 100.

Basically, the device 200 may be formed by applying process strategies as discussed above with the replacement gate approach described with reference to the device 100. That is, after completing the basic transistor configuration, i.e., forming the gate electrode structure 260 having the desired lateral dimensions and forming the drain and source regions 251, possibly in combination with additional contact areas 252, for instance in the form of a metal silicide, the materials of the contact level 220 may be deposited and may be planarized so as to expose the surface of a placeholder material of the gate electrode structure 260. After the removal thereof and exposing the surface 202S of the active region 202A, the base dielectric material 264A may be formed on the basis of a thermal process, as described above, followed by the deposition of the high-k dielectric material 264B, possibly in combination with the deposition of the material 265A, as is also discussed above. Thereafter, the low temperature anneal process 208 may be applied in the presence of a process ambient 208A in order to reduce the electrically effective equivalent thickness of the high-k dielectric material 264 and to provide the superior interface characteristics, as described above. It should be appreciated that, due to the low temperature used in the anneal process 208, the temperature-sensitive materials 252 may be formed without being affected by the process 208.

It should be appreciated that, in other illustrative embodiments, when the base material 264A is to be provided on the basis of a high temperature thermal oxidation process, the material may be provided in an earlier manufacturing stage, i.e., upon forming the gate electrode structure 260 in the form of a placeholder gate electrode structure, while removal of any placeholder material may be provided on the basis of a highly selective etch ambient, thereby substantially not unduly affecting the material 264A so that the high-k dielectric layer 264B may be deposited and processed on the basis of the low temperatures without being restricted to low process temperatures upon forming the material 264A. In still other cases, low temperature thermal oxidation and/or nitridation processes may be applied upon forming the layer 264A, as is also discussed above. Thereafter, the further processing may be continued by depositing any further materials as required for completing the gate electrode structure 260.

FIG. 2f schematically illustrates the semiconductor device 200 in a further advanced manufacturing stage. As shown, the gate electrode structure 260 may comprise, in addition to the material layer 265A, one or more further metal-containing electrode materials, such as the materials 265B, 265C, in combination with a highly conductive electrode metal 269, such as aluminum, aluminum alloys and the like. To this end, any appropriate deposition techniques may be applied, followed by the removal of any excess material using CMP, etch techniques, electromigration-CMP and the like.

It should be appreciated that, although the temperature-sensitive material 252 may be present in this manufacturing stage, in other cases, the material 252 may be formed in a later manufacturing stage, as is also described above with reference to the device 100.

FIG. 2g schematically illustrates the semiconductor device 200 according to further illustrative embodiments. As shown, a plurality of transistors 250 and thus a plurality of gate electrode structures 260 may be formed in and above the active region 202A. For example, the transistors 250 may represent a plurality of closely spaced transistors, such as P-channel transistors and the like, which may require sophisticated high-k metal gate electrode structures. Moreover, in sophisticated applications, typically a space 260S between neighboring gate electrode structures 260 may result in significant yield losses upon forming contact elements so as to connect to the drain and source regions 251 or any contact regions 252 formed therein, so that frequently a self-aligned contact regime may be applied. In this case, the gate electrode structures 260, which are still reliably encapsulated by means of the cap layers 267 and the spacer structures 263, may be exposed to a reactive etch atmosphere in order to remove a dielectric material of the contact level 220 so as to finally expose drain and source regions 251 or the contact regions 252, if already formed therein. Thereafter, the contact regions 252 may be formed, if not already provided, and any appropriate conductive contact material 223A may be deposited and any excess portion may be removed so as to finally expose the placeholder material 262 of the gate electrode structures 260. Consequently, in this case, the further processing may be continued by applying a replacement gate approach, as is, for instance, described above with reference to FIGS. 2e and 2f, without compromising the corresponding self-aligned contact elements 223 and the contact regions 252 due to the low temperatures applied during the anneal process 208 (FIG. 2e).

As a result, the present disclosure provides efficient process techniques in which sophisticated high-k dielectric materials may be formed on the basis of thermally grown base materials, such as oxide materials, oxide/nitride materials and the like, which may be formed at any appropriate manufacturing stage by using well-controllable processes on the basis of gaseous process atmospheres, while, in some illustrative embodiments, also the thermally grown base materials may be formed on the basis of process temperatures that are compatible with the overall device configuration. After the deposition of a high-k dielectric layer, a low temperature anneal process may be applied, for instance in an SPA process regime, by using a reducing atmosphere, thereby significantly reducing the electrically effective equivalent thickness of the high-k dielectric material, while also providing superior interface characteristics. Thus, a low thickness and thus a high capacitive coupling of the high-k dielectric material may be achieved, which may result in reduced threshold voltages, for instance for sophisticated P-channel transistors, while at the same time high reliability values may be achieved. Furthermore, due to the low temperature used in the anneal process, compatibility with any process strategy is accomplished.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
performing an oxidation process in a gaseous oxidizing atmosphere so as to form an oxide layer on an exposed silicon-containing surface of a semiconductor region of a semiconductor device;
forming a layer of a high-k dielectric material on said oxide layer;
performing a heat treatment at a temperature of 500° C. or less so as to form a gate dielectric material from said oxide layer and said layer of a high-k dielectric material; and
forming a gate electrode structure of a field effect transistor on the basis of said gate dielectric material.

2. The method of claim 1, wherein said heat treatment is performed in a reducing ambient.

3. The method of claim 2, wherein said reducing ambient is established by using oxygen and at least one of nitrogen and hydrogen.

4. The method of claim 1, wherein said heat treatment is performed in the presence of a plasma established in a slot plane antenna process chamber.

5. The method of claim 4, wherein said heat treatment is performed at a temperature of 300° C. and less.

6. The method of claim 1, further comprising forming at least one metal-containing electrode material on said gate dielectric material.

7. The method of claim 1, wherein forming a gate electrode structure on the basis of said gate dielectric material comprises forming a semiconductor material above said gate dielectric material and patterning said semiconductor material and said gate dielectric material.

8. The method of claim 1, wherein forming a gate electrode structure on the basis of said gate dielectric material comprises forming a placeholder structure above said gate dielectric material and replacing a placeholder material with one or more metal-containing electrode materials while preserving said gate dielectric material.

9. The method of claim 1, wherein forming a gate electrode structure on the basis of said gate dielectric material comprises forming drain and source regions in said semiconductor region in the presence of a placeholder structure, and removing a placeholder material of said placeholder structure so as to provide said exposed silicon-containing surface.

10. The method of claim 1, further comprising forming a metal/silicon compound in said semiconductor region prior to forming said gate dielectric material.

11. The method of claim 1, further comprising forming a metal-containing electrode material above said layer of a high-k dielectric layer, wherein said heat treatment is performed in the presence of said metal-containing electrode material.

12. The method of claim 11, further comprising forming a second metal-containing electrode material on said metal-containing electrode material without intermittently exposing said metal-containing electrode material to ambient atmosphere.

13. A method of forming a high-k dielectric material, the method comprising:
forming a first dielectric layer on an exposed silicon-containing semiconductor surface in a gaseous reactive process atmosphere;
forming a high-k dielectric layer on said first dielectric layer; and
performing an anneal process in a reducing atmosphere at a temperature of 500° C. or less.

14. The method of claim 13, wherein said reducing atmosphere is established on the basis of oxygen and at least one of nitrogen and hydrogen.

15. The method of claim 14, wherein said temperature is adjusted to 200° C. or less.

16. The method of claim 15, wherein said reducing atmosphere is established by establishing a plasma.

17. The method of claim 13, further comprising forming a metal-containing material layer on said high-k dielectric layer prior to performing said anneal process.

18. The method of claim 13, wherein said first dielectric layer is formed by a thermal oxidation process.

19. A method, comprising:
exposing a top surface of a placeholder material of a gate electrode structure of a semiconductor device;
removing said placeholder material so as to expose a silicon-containing surface of a semiconductor region;
forming a gate dielectric material on said silicon-containing surface by thermally oxidizing said silicon-containing surface, forming a high-k dielectric layer on said oxidized silicon-containing surface and performing an anneal process; and
forming a metal-containing electrode material above said gate dielectric material.

20. The method of claim 19, wherein said anneal process is performed at a temperature of 500° C. or less in a reducing atmosphere.
